(19) United States
(12) Patent Application Publication
(10) Pub. No.: US 2022/0021176 A1
(43) Pub. Date: Jan. 20, 2022

(54) DEVICE FOR GENERATING LASER RADIATION

(71) Applicant: FERDINAND-BRAUN-INSTITUT GGMBH, LEIBNIZ-INSTITUT FÜR HÖCHSTFREQUENZTECHNIK, Berlin (DE)

(72) Inventors: Nils WERNER, Gilching (DE); Julian HOFMANN, Germering (DE); Roland BEGE, Berlin (DE); Alexander SAHM, Berlin (DE); Katrin PASCHKE, Michendorf (DE)

(73) Assignee: FERDINAND-BRAUN-INSTITUT GGMBH, LEIBNIZ-INSTITUT FÜR HÖCHSTFREQUENZTECHNIK, Berlin (DE)

(21) Appl. No.: 17/296,114

(22) PCT Filed: Nov. 20, 2019
(86) PCT No.: PCT/EP2019/081913

§ 371 Date: May 21, 2021

(30) Foreign Application Priority Data
Nov. 23, 2018 (DE) 10 2018 129 623.1

(51) Int. Cl. H01S 3/109; H01S 3/10; H01S 3/063; H01S 3/08; G02F 1/355; G02F 1/377

(52) U.S. Cl. CPC H01S 3/109; H01S 3/1001; G02F 1/3775; H01S 3/08059; G02F 1/3558; H01S 3/063

(57) ABSTRACT

The present invention relates to a device for generating laser radiation.

A problem addressed by the present invention is that of specifying a device for generating laser radiation using a nonlinear crystal, which device has a simple construction and low optical losses.

The device according to the invention comprises an optical amplifier having an active zone, wherein the optical amplifier has a front facet and a rear facet, between which the active zone extends; and a resonator having a first resonator element and a second resonator element, between which the optical amplifier extends, wherein the first resonator element is arranged on a side of the active zone facing away from the front facet and the second resonator element is arranged on a side of the active zone facing the front facet, and wherein the second resonator element comprises a nonlinear crystal having periodic poling.

This application is the U.S. National Stage of International Application No. PCT/EP2019/081913, filed Nov. 20, 2019, which claims foreign priority benefit under 35 U.S.C. § 119 of German Application No. 10 2018 129 623.1, filed Nov. 23, 2018.

### DESCRIPTION

The present invention pertains to a device for generating laser radiation. The present invention particularly pertains to an efficient device for generating laser radiation by means of frequency doubling.

### PRIOR ART

So-called nonlinear materials, the electric polarization of which reacts to an external electric field in a nonlinear manner, make it possible to convert light to a different wavelength (nonlinear frequency conversion). Examples of such processes are frequency doubling (second harmonic generation, SDH) or parametric fluorescence (spontaneous parametric down conversion, SPDC). Although various designs are available for the concrete implementation, they are related with respect to the basic principle and the properties described herein. Since the nonlinear mediums typically have a crystalline structure, the following description refers exclusively to crystals. It is possible to use the crystal as volumetric material, wherein the light from the source is suitably shaped by means of optical elements such that a certain beam profile or caustic is respectively present in the crystal. Furthermore, the crystal may also contain waveguide structures that guide the irradiated and/or the generated light (ridge waveguide structure, channel waveguide, etc.). This requires coupling of the irradiated light into this waveguide structure. Combinations of both principles also possible, i.e. waveguide in one dimension and volumetric material in the other dimension (planar waveguide structure).

So-called phase matching between the involved light beams has to be fulfilled in order to ensure that the nonlinear processes take place as efficiently as possible.

This can be achieved with two widely used methods. On the one hand, it is possible to utilize double-refracting properties of the crystals, wherein a precise alignment of the light beams and the crystallographic axes of the crystal is required. Due to the double-refracting properties of the crystal, the refractive index of the irradiated and generated light changes depending on the angles of the light beams relative to the crystallographic axes.

Another method is known as quasi-phase matching. In this case, the nonlinear crystal is periodically poled such that a layer sequence of alternating orientation of the electric polarization is present along the beam direction of the irradiated light. The period of this poling is chosen in such a way that phase matching is fulfilled for the desired nonlinear process. The optimal poling depends on the type of process, the wavelength of the irradiated light and the refractive indexes of the crystal for the wavelength of the irradiated light and the wavelength of the light to be generated. For example, the periodicity of the poling may be chosen in such a way that efficient frequency doubling for exactly one wavelength is possible. Another wavelength in turn requires a slightly different periodicity.

In both methods, it is necessary to precisely adjust the wavelength of the irradiated light and to precisely control all crystal parameters that influence phase matching. Since the refractive index of the crystal has a particularly strong influence on phase matching and this refractive index in turn depends on the crystal temperature, it is primarily necessary to actively control the crystal temperature. In complete systems consisting of laser source and crystal, the laser source and the crystal therefore have to be controlled individually by means of corresponding control circuits.

The emission wavelength changes, in particular, in semiconductor lasers with integrated wavelength stabilization (e.g. Distributed-Bragg-Reflector (DBR)) upon a variation of the output power or the temperature. Abrupt changes of the emission wavelength (so-called mode jumps) can occur during these events. The wavelength change during a mode jump is inversely related to the resonator length of a laser. In the case of semiconductor lasers with typical resonator lengths of less than one centimeter, the wavelength change may be as high as a few ten picometers and therefore negatively affect the nonlinear process. It is therefore disadvantageous that the use of such lasers requires an elaborate control technology in order to individually adjust operating parameters of the laser and/or the crystal at each operating point. The main problem can be seen in the fact that the laser source and the crystal represent for nonlinear processes two separate assemblies that have to be individually and independently controlled.

The use of periodically poled crystals also leads to other disadvantages that result from the periodic poling. Small changes in the refractive index occur at the boundaries between individual polarization layers such that a small portion of the light is reflected at each of these domain boundaries. Due to the periodic arrangement of the poling, the nonlinear crystal furthermore acts like a Bragg grating that has typical resonance maxima at certain wavelengths. The position of these resonances depends on the periodicity of the poling and the refractive index at the respective wavelength. The resonances are therefore influenced by the choice of periodic poling, but it is necessary to distinguish between the wavelength, for which the periodic poling was optimized in the sense of an efficient nonlinear process, and the wavelength, at which a resonance occurs. Since both have different dependencies, there are poling periods that cause resonance and the efficient nonlinear process to occur at the same wavelength. Vice versa, they can also differ significantly if the poling period is only slightly varied. Since the refractive indexes particularly vary with the temperature and the resonance and the nonlinear process scale differently with the refractive index, an adjustment as to whether both effects occur at the same wavelength can be realized to a certain extent by means of the temperature.

FIG. 1a and FIG. 1b shows the reflection spectrums for two different periodically poled lithium niobate crystals at a temperature of 25° C. Both crystals have a ridge waveguide structure, i.e. the light is guided through the crystal in a ridge waveguide. The crystal in FIG. 1a) is optimized for SHG at a wavelength of 1122 nm. However, the Bragg resonance in the observed wavelength range lies at 1100 nm. The crystal in FIG. 1b) is a crystal for SHG at 1070 nm, in which a Bragg resonance occurs at a slightly smaller nanometer value of 1065 nm. Especially the intensive Bragg resonances, which reflect nearly 10% of the irradiated light at this wavelength, can significantly interfere with the light source used during its operation, particularly if the resonance lies near the wavelength for the nonlinear frequency conversion, i.e. near the emission wavelength of the light source. However, the observed noise background beyond the Bragg resonances with reflectivities of 0.001% to 0.1% can also become a problem for the stable operation of a light source in the form of a laser.

Especially semiconductor lasers can sometimes react strongly to back reflections and as a result show abrupt changes of the output power and their spectral properties. Since frequency conversion usually requires the wavelength to remain stable in a very narrow window (wavelength acceptance) and is also highly dependent on the irradiated power, a reliable operation can only be achieved in that the laser is affected as little as possible by back reflections.

The basic explanation for the disturbed operation of the laser under the influence of back reflections is that different resonators compete with one another. There is on the one hand the resonator that forms part of the laser (internal resonator) and on the other hand the resonator that is formed of the laser and the nonlinear medium (external resonator). The main problem in this respect can also be seen in that laser and crystal are two individual assemblies and in the case of the laser react to external influences.

Different conventional approaches for solving or at least mitigating this problem have been previously disclosed.

An optical isolator between laser source and nonlinear medium makes it possible to diminish the back reflections by several orders of magnitude such that the external resonator experiences significant optical losses (the resonator quality is reduced) and the laser operation is no longer disturbed or only insignificantly disturbed. However, the use of an optical isolator increases the costs and the complexity of a setup. Another problem with respect to micro-integration can be seen in that miniaturized optical isolators are not available for all wavelengths and furthermore not suitable for all power classes. In addition, optical isolators always lead to certain optical losses due to the absorption of light.

In a second approach, the laser can be optimized by increasing the quality of the internal resonator such that this laser also operates in a stable manner up to a certain level when back reflections occur. For example, the front facet reflectivity can be increased in semiconductor lasers. However, it is disadvantageous that the maximal output power of the laser is typically reduced in this case. Such optimizations are not possible with certain laser types for design-related reasons.

The third approach is to alter the crystal such that back reflections are reduced or at least no longer end up in the laser. This also essentially corresponds to a reduction of the quality of the external resonator. The periodic poling may be realized in such a way that the domain boundaries of the poling no longer extend perpendicular to the irradiated beam. Although back reflections can occur in this case, the majority is reflected back at an angle such that these back reflections do not reach the laser source. The disadvantages of this approach are an increased effort for generating the periodic poling in the crystal and a potentially reduced efficiency of the nonlinear process. Furthermore, a small portion of the light is still reflected in the direction of the laser source at all times.

The third approach is already known in the prior art for deflecting reflections on the input and output facets of the crystal from the beam sources. The residual reflectivity of the facets typically lies around 0.1% despite antireflection coatings. In this case, the facets are realized in such a way that the light beams have an angle of incidence of a few degrees relative to the facet.

The conventional devices for frequency doubling by using nonlinear crystals therefore either lead to optical losses or require an increased manufacturing effort. Furthermore, an increased control effort is required for controlling the operating parameters of the laser and the crystal individually.

### DISCLOSURE OF THE INVENTION

An objective of the present invention therefore can be seen in disclosing a device that serves for generating laser radiation by using a nonlinear crystal and eliminates the aforementioned disadvantages.

According to an aspect of the present invention, the device for generating laser radiation comprises an optical amplifier with an active zone, wherein the optical amplifier has a front facet and a rear facet, between which the active zone extends; and a resonator with a first resonator element and a second resonator element, between which the optical amplifier extends, wherein the first resonator element is arranged on a side of the active zone facing away from the front facet and the second resonator element is arranged on a side of the active zone facing the front facet, and wherein the second resonator element comprises a nonlinear crystal with periodic poling.

In conventional devices, the resonator around the active medium is always formed independently of the crystal. In the case of periodically poled crystals, it is always attempted to reduce the quality of the external resonator or to increase the quality of the internal resonator (i.e. the optical amplifier). The idea of the present invention can be seen in purposefully using the crystal as external resonator mirror. To this end, the already existing back reflections generated by a crystal with periodic poling are used for generating spectrally selective back reflections such that the periodically poled crystal can serve as resonator mirror.

In this case, the resonator around the amplifier medium (optical amplifier) required for the laser operation is formed by the crystal itself on the decoupling side of the laser radiation. In other words, the optical amplifier according to one design variation only reaches the laser threshold due to the back reflection of the periodic poling of the crystal.

Although a majority of the optical power (e.g. for frequency doubling) propagates through the crystal and can be used for nonlinear processes, a portion of the radiation is simultaneously reflected back to the optical amplifier on the domain boundaries of the periodic poling and thereby ensures the laser operation.

A rear resonator mirror (resonator element) is likewise located behind the optical amplifier. In order to realize an efficient utilization of the back reflection on the crystal, a design variation proposes to provide an amplifier, in which the reflectivity of the facet of the optical amplifier located between the amplifier and the crystal (front facet) is correspondingly related to the reflectivity of the crystal due to the periodic poling at the operating wavelength of the amplifier. The ratio of the reflectivity of the crystal (referred to the operating wavelength of the amplifier) to the reflectivity of the front facet of the amplifier (likewise referred to the operating wavelength of the amplifier) should not be smaller than 1 and preferably is greater than 10, particularly greater than 100.

Since the crystal is purposefully used as external resonator, the crystal is in the complete system responsible for the wavelength selection, as well as the nonlinear process. It suffices to actively control only the crystal, e.g. with respect to the temperature, i.e. the temperature has to be adapted by a control circuit in such a way that the optimal frequency conversion always takes place and the frequency-converted radiation therefore is maximal with respect to its power. If applicable, the optical amplifier only has to be passively controlled with respect to the temperature such that it can dissipate the arising heat losses, but this does not require an elaborate control circuit. Since the external resonator is longer than the internal resonator of the amplifier, the wavelength changes caused by mode jumps are significantly reduced such that they likewise no longer represent a problem. It is furthermore possible to forgo optical isolators between the amplifier and the crystal. Another advantage can be seen in that it is not necessary to increase the reflectivity of the front facet of the amplifier in order to suppress potential back reflections. According to one design variation, an antireflection coating (or other antireflection devices) may be used on the input facet of the crystal.

According to a design variation of the invention, the optical amplifier is realized in the form of an electrically pumped optical semiconductor amplifier. In this case, the active zone is designed for emitting radiation of a first wavelength (operating wavelength of the amplifier). A design variation furthermore proposes that the resonator is designed for increasing the intensity of the radiation of the first wavelength within the resonator beyond the laser threshold such that laser radiation of the operating wavelength can be converted in the crystal (frequency doubling) and decoupled for further use via an output facet of the crystal. The crystal therefore serves for forming a resonator in order to generate laser radiation by using the electrically pumped amplifier on the one hand and for generating secondary laser radiation by means of frequency conversion of the primary laser radiation generated by the amplifier and the resonator (crystal) on the other hand.

According to a design variation of the invention, the ratio of the reflectivity of the crystal due to the periodic poling for the first wavelength to the reflectivity of the front facet of the amplifier for the first wavelength is greater than 10, preferably greater than 100, particularly greater than 500. According to a design variation of the invention, the reflectivity of the front facet of the amplifier for the first wavelength is smaller than 0.001 (i.e. smaller than 0.1% or smaller than 10⁻³), preferably smaller than 10⁻⁴, particularly smaller than 10⁻⁵, especially smaller than 10⁻⁶.

According to a design variation, the nonlinear crystal is designed for converting the radiation (of the first wavelength) generated by the amplifier into radiation of a second wavelength by means of nonlinear frequency conversion. The crystal is designed for subjecting the radiation coupled in via the input facet to a nonlinear conversion process. The first wavelength preferably amounts to double the second wavelength. In this case, it is preferred that the crystal is adapted for frequency doubling to the wavelength of the amplifier. In other words, it is preferred that the crystal has its maximal conversion efficiency at the first wavelength. Other nonlinear conversion processes such as SPDC, for which the crystal and the amplifier are adapted with respect to the respective maximal conversion efficiency, may be considered as an alternative to frequency doubling.

The nonlinear crystal with periodic poling preferably is designed in such a way that a difference between the wavelength, for which the crystal has a maximal reflectivity, and the wavelength, for which the crystal has a maximal conversion efficiency, is smaller than 30 nm, preferably smaller than 25 nm, particularly smaller than 20 nm, especially smaller than 15 nm, wherein said wavelength difference is in a particularly preferred design variation smaller than 10 nm, especially smaller than 5 nm.

The periodic poling preferably is homogenous periodic poling. In this context, homogenous means that the periodicity of the poling is constant over the entire length of the periodic poling.

The periodic poling preferably extends over the entire length of the crystal.

The reflectivity of the crystal is caused by the domain boundaries. In this case, the individual domain boundaries have a constant reflectivity over the length of the crystal and also over the cross-sectional area of the crystal (at least the cross-sectional area occupied by the guided light).

With respect to the wavelength difference, one can distinguish between the three following instances.

In the first (above-described) instance, the crystal is designed for a wavelength at a certain temperature such that the reflection maximum and the wavelength are for maximal conversion efficiency identical.

In the second instance, the wavelengths slightly deviate from one another. In this case, it can be ensured that both wavelengths correspond to one another by changing the temperature or other parameters. However, this common wavelength slightly shifts in this case and this wavelength shift has to be taken into account in the design of the arrangement. In addition, this method is highly dependent on the properties of the crystal and typically only suitable for small wavelengths deviations (preferably up to 5 nm). The reason for this can be seen in that the wavelength only changes slowly with the temperature and one (computationally) quickly arrives at temperatures that cannot be sensibly implemented, e.g. if—depending on crystal and amplifier—a difference of 15 nm should be compensated.

In the third instance, the wavelength difference is even greater such that a temperature control (alone) is likewise not sensible.

However, it is still possible to use the crystal as resonator mirror.

On the one hand, the rather homogenous noise background at approximately 0.1% reflectivity (see FIG. 1a) is used rather than the wavelength-selective property of the sharply defined resonance maximum. However, this requires the incorporation of an additional wavelength-selective element into the resonator such that the laser operation through this element takes place at the wavelength for the effective nonlinear process and not at the resonant wavelength.

According to a design variation, no optical isolators and no optical filters are respectively arranged between the front facet of the optical amplifier and the input facet of the crystal.

According to a design variation, it is preferred that the nonlinear crystal has beam-guiding elements such as a waveguide, which is aligned in such a way that the radiation guided by the waveguide extends at an angle to the domain boundaries of the periodic poling of the crystal (all of which preferably are aligned parallel to one another), wherein said angle lies between 80 and 100°, preferably between 85 and 95°, particularly between 88 and 92° (full circle 360°). The inclined arrangement of the domain boundaries serves for lowering the reflectivity due to the periodic poling, which typically amounts to 5% (see FIGS. 1a and 1b), to preferably 1% in order to achieve an optimal efficiency of the complete system. The reflectivity of the crystal is exclusively caused by the disturbances of the refractive index occurring on the domain boundaries of the periodic poling. The periodic poling and therefore also the disturbances of the refractive index must be homogenously distributed over the entire boundary surface of the domains.

In an alternative yet likewise preferred design variation, the nonlinear crystal does not have any beam-guiding elements such as a waveguide. In this design variation, it is also preferred that the radiation emitted by the optical amplifier (and coupled into the crystal for the purpose of frequency conversion) extends perpendicularly along the domain boundaries of the periodic poling of the crystal. In contrast to the preceding design variation with a crystal having a waveguide, the reflectivity of the periodic poling is lower in crystals without beam-guiding elements, which is why a perpendicular arrangement of the domain boundaries relative to the radiation is preferred.

The facets of the crystal preferably are inclined relative to the principal direction of the radiation in the crystal because an additional resonator, which would once again disturb the laser operation, is otherwise formed by the facets. An angle between the facets of the crystal and the radiation propagating in the crystal preferably amounts to between 1° and 10°, particularly between 2° and 5° (full circle 360°).

The amplifier preferably has a ridge waveguide. The crystal is according to a design variation made of lithium niobate.

According to a design variation, the rear resonator mirror may be formed by integrating a surface grating into the end or rear section of the ridge waveguide (facing away from the amplifier). This is particularly preferred if the difference between the wavelength, for which the crystal has a maximal reflectivity, and the wavelength, for which the crystal has a maximal conversion efficiency, is greater than 5 nm, preferably greater than 10 nm, particularly greater than 15 nm.

The rear resonator mirror may be alternatively formed by the rear facet of the optical amplifier. This is particularly preferred if the difference between the wavelength, for which the crystal has a maximal reflectivity, and the wavelength, for which the crystal has a maximal conversion efficiency, is smaller than 10 nm, preferably smaller than 5 nm and particularly smaller than 3 nm.

### BRIEF DESCRIPTION OF THE DRAWINGS

Exemplary embodiments of the invention are described below with reference to the corresponding drawings. In these drawings:

FIGS. 1a and 1b show reflection spectrums of two periodically poled ridge waveguide crystals,

FIG. 2 shows a schematic sectional representation of an inventive device for stabilizing an optical amplifier with the aid of reflections of a periodically poled crystal for frequency conversion,

FIG. 3a shows a schematic top view of a device according to a first design variation of the invention,

FIG. 3b shows a schematic side view (sectional representation) of a device according to the first design variation of the invention,

FIG. 3c shows a schematic side view (sectional representation) of a device according to another design variation of the invention, and

FIG. 4 shows a sectional representation of the semiconductor amplifier illustrated in FIGS. 3a and 3b.

### DETAILED DESCRIPTION OF THE DRAWINGS

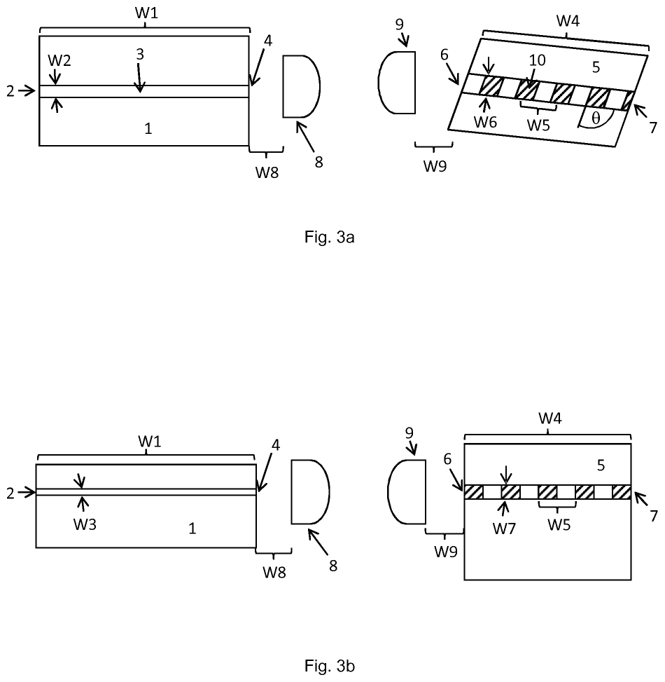

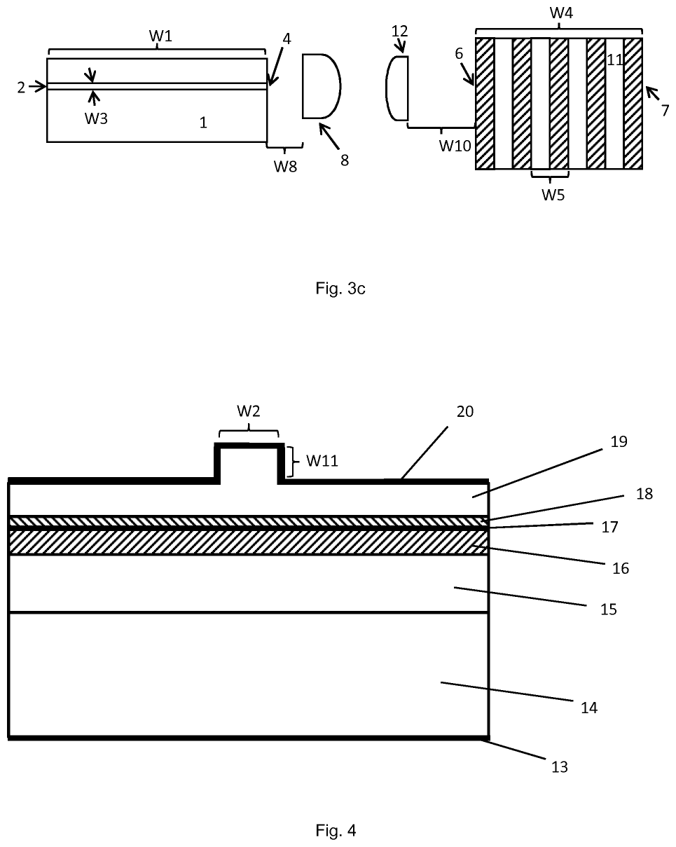

FIGS. 3a and 3b show a top view and a sectional representation of a device according to a first design variation, in which a periodically poled crystal with ridge waveguide is used as resonator mirror for a semiconductor amplifier with a ridge waveguide structure.

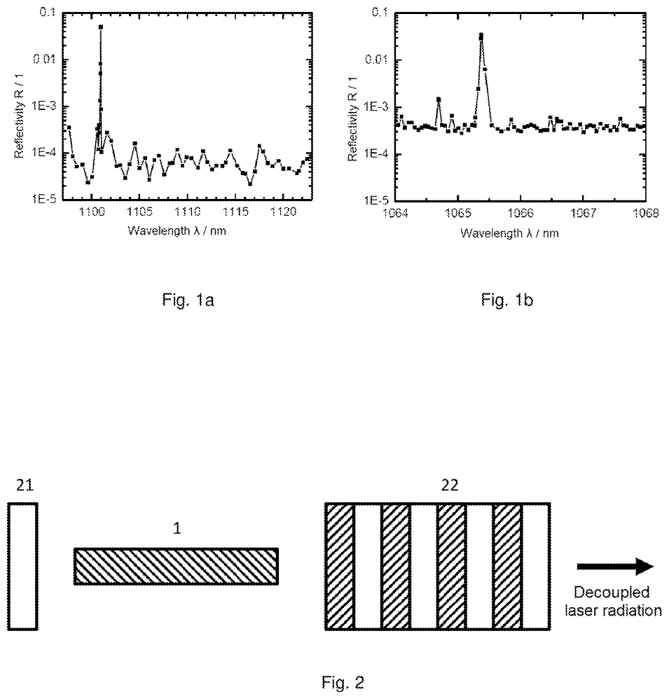

The periodically poled crystal 5 has the same periodic poling as the crystal, the reflection spectrum of which is illustrated in FIG. 1b), but the domains are arranged at an angle θ=92° relative to the waveguide 10. The aim is to additionally use the reflection spectrum of the crystal 5 as spectral filter and to thereby define the emission wavelength of the laser operation at 1065 nm. A variation of the temperature of the crystal and the different scaling of the Bragg resonances and the phase matching for the frequency doubling ultimately make it possible to adjust the emission wavelength of the laser in such a way that light is during passage through the crystal 5 optimally converted into frequency-doubled radiation (SHG).

The semiconductor amplifier 1 was processed by means of organometallic vapor phase epitaxy on gallium arsenide (GaAs). The amplifier 1 has a length W1=4 mm and the ridge waveguide 3 has a width W2=4 μm. A planar waveguide with a thickness W3=4.8 μm is formed in the vertical direction. The rear facet 2 is mirror-coated and therefore represents the rear resonator mirror (21 in FIG. 2). The front facet 4 has an antireflection coating and a reflectivity of less than 0.01% for the operating wavelength of 1065 nm.

The periodically poled crystal 5 consists of lithium niobate and is commercially available, for example, from HP Photonics Corp. The crystal 5 has a length W4=10 mm whereas the period of the periodic poling W5 amounts to approximately 6.6 μm. The domains of the periodic poling are arranged at an angle θ=92° relative to the waveguide. The ridge waveguide 10 has a width W6 of approximately 6 μm and a height W7=4 μm. Although the ridge waveguides 3, 10 of the amplifier 1 and the crystal 5 have slightly different dimensions, the basic modes guided therein (i.e. at approximately 1065 micrometer) largely correspond. Consequently, two aspherical lenses 8 and 9 with a focal length of 4 mm are used for optically coupling both components. These lenses are respectively positioned in such a way that the distance W8 from the front facet 4 of the amplifier 1 and the distance W9 from the input facet 6 of the crystal 5 respectively correspond to the effective focal length of the lenses 8 and 9. The distance between the two lenses 8, 9 may amount up to several meters as long as it does not reach the order of magnitude of the Rayleigh length of the laser beam to be coupled. This length usually is greater than 1 m when lenses with a focal length of 4 mm are used.

In comparison with the crystal 5, the crystal 11 has no beam-guiding element and the radiation being coupled in therefore propagates freely through the crystal. A lens 12 that differs from the lens 9 consequently is used for the coupling.

The vertical layer structure of the semiconductor amplifier 1 is illustrated in FIG. 4. The epitaxic layer sequence is applied on a GaAs substrate 14. An InGaAs triple quantum well forms the active zone 17, which is asymmetrically arranged in a waveguide. The waveguide is composed of an n-doped AlGaAs waveguide core 16 with a thickness of 4000 nm and a p-doped AlGaAs waveguide core 18 with a thickness of 800 nm. This results in a total of 4.8 μm, which is indicated as W3 in FIG. 3b. The waveguide is respectively surrounded by an n-doped outer layer 15 with a thickness of 500 nm and a p-doped outer layer 19 with a thickness of 500 nm.

The ridge waveguide 3, which is produced by means of edging, once again protrudes beyond the outer layer 19 with the height W11 of 800 nm. Electric contacting is ultimately ensured by the p-contact 20 and the n-contact 13.

Since the Bragg resonances of the crystal 5 sometimes deviate from the optimal wavelength for frequency doubling by several 10 nm, it is not always possible to use the Bragg resonances as wavelength-selective element and to simultaneously achieve optimal conditions for the frequency conversion. Nevertheless, the non-evanescent reflectivity of the crystal of at least approximately 0.01% can be used for achieving the laser threshold due to periodic poling. The front facet 4 of the amplifier has to be highly non-reflecting and have a reflectivity of 10⁻⁶ or less. In this case, the crystal 5 once again acts as front resonator mirror 22, but without wavelength-selective effect. The rear resonator mirror 21 has to be realized in the form of a wavelength-selective element in order to still define the emission wavelength. One potential design is the integration of a surface grating directly into the rear section of the ridge waveguide 3.

### REFERENCE LIST

1 Optical amplifier
2 Rear facet
3 Ridge waveguide
4 Front facet
5 Optical crystal (periodically poled)
6 Input facet
7 Output facet
8 Lens
9 Lens
10 Ridge waveguide (crystal)
11 Optical crystal (periodically poled without beam-guiding elements)
12 Lens
13 n-contact
14 Substrate
15 n-conducting outer layer
16 n-conducting core layer
17 Active zone
18 p-conducting core layer
19 p-conducting outer layer
20 p-contact
21 Rear resonator mirror (first resonator element)
22 Front resonator mirror (second resonator element)

1. A device for generating laser radiation, comprising:
a) an optical amplifier with an active zone,
b) wherein the optical amplifier has a front facet and a rear facet, between which the active zone extends; and
c) a resonator with a first resonator element and a second resonator element, between which the optical amplifier extends, wherein the first resonator element is arranged on a side of the active zone facing away from the front facet and the second resonator element is arranged on a side of the active zone facing the front facet,
d) wherein the second resonator element comprises a nonlinear crystal with periodic poling,
e) wherein the device is configured to only actively adjust the temperature of the nonlinear crystal and to passively adjust the temperature of the optical amplifier.

2. The device of claim 1, wherein the optical amplifier is realized in the form of an electrically pumped optical semiconductor amplifier, and wherein the active zone is designed for emitting radiation of a first wavelength.

3. The device of claim 2, wherein the ratio of the reflectivity of the crystal for the first wavelength to the reflectivity of the front facet for the first wavelength is greater than or equal to 10.

4. The device of claim 3, wherein the ratio of the reflectivity of the crystal for the first wavelength to the reflectivity of the front facet for the first wavelength is greater than or equal to 100.

5. The device of claim 2, wherein a reflectivity of the front facet for the first wavelength is smaller than 0.001.

6. The device of claim 2, wherein the nonlinear crystal is designed for converting radiation of the first wavelength into radiation of a second wavelength by means of nonlinear frequency conversion.

7. The device of claim 6, wherein the first wavelength amounts to double the second wavelength.

8. The device of claim 1, wherein no optical isolators and/or no optical filters are arranged between the front facet of the optical amplifier and an input facet of the crystal.

9. The device of claim 1, wherein the optical amplifier and the crystal are aligned relative to one another in such a way that the radiation emitted by the optical amplifier is coupled into an input facet of the crystal.

10. The device of claim 9, wherein the boundaries of periodically arranged polarity layers of the crystal extend at an angle unequal to 90° relative to the radiation coupled into the crystal.

11. The device of claim 9, wherein the boundaries of periodically arranged polarity layers of the crystal extend perpendicular to the radiation coupled into the crystal, and
wherein the nonlinear crystal comprises no beam-guiding elements.

12. The device of claim 1, wherein the periodic poling is a homogenous periodic poling.

13. The device of claim 1, wherein the periodic poling extends over the entire length of the crystal.
